(19) United States
(12) Patent Application Publication
(10) Pub. No.: US 2020/0383196 A1
(43) Pub. Date: Dec. 3, 2020

(54) METHOD AND SYSTEM FOR MEASURING PLASMA EMISSIONS IN A PLASMA PROCESSING REACTOR

(71) Applicant: Ioneer, LLC, Pleasanton, CA (US)

(72) Inventor: Anthony CHEN, Pleasanton, CA (US)

(21) Appl. No.: 16/604,783

(22) PCT Filed: Apr. 13, 2018
(86) PCT No.: PCT/US18/27636

§ 371 Date: Oct. 11, 2019

Related U.S. Application Data
(60) Provisional application No. 62/485,664, filed on Apr. 14, 2017.

(51) Int. Cl. H05H 1/00; H01J 37/32; H01L 21/66; H05H 1/24; H01L 21/67

(52) U.S. Cl. CPC H05H 1/0025; H01J 37/32917; H01L 21/67069; H05H 1/24; H01L 22/30

(57) ABSTRACT

A method of characterizing a Plasma Processing Reactor (PPR) by measuring the electromagnetic (EM) emissions of a plasma inside the PPR using an Optical Plasma Monitoring Apparatus (OPMA) is described. The OPMA contains a plurality of photo-sensors that can measure EM emissions of narrow and/or broad spectral regions at various selected positions on the OPMA, and record them as a function of time. The OPMA can have substantially similar dimensions of a workpiece to facilitate loading and unloading into the PPR.

### CROSS-REFERENCE TO RELATED APPLICATION

This application claims priority to U.S. Provisional Application 62/485,664, titled “Method of and Apparatus for Measuring Plasma Emissions in a Plasma Processing Reactor” and filed on Apr. 14, 2017, the disclosure of which is incorporated herein by reference in its entirety.

### TECHNICAL FIELD

The disclosure relates generally to semiconductor testing equipment. More specifically, certain embodiments of the technology relate to a method and system for testing process information of semiconductor equipment.

### BRIEF SUMMARY

The present disclosure relates to characterization of Plasma Processing Reactors (PPRs) in the semiconductor and display fabrication industry. PPRs are used extensively in both industries for workpiece etch processing, deposition processing, photoresist removal, and residue cleaning steps. Characterization of PPRs before and while in use is critical to achieving the required specifications of corresponding processing step.

In a semiconductor fabrication etch processing step, for example, each die or chip on a semiconductor wafer or workpiece should be processed to achieve substantially the same targeted performance. Thus, it is necessary that each die on the wafer is processed with substantially the same etch result. Because plasma characteristics and etch and byproduct gas flows are inherently non-uniform and can drift, fingerprinting and repeated monitoring of the plasma emission characteristics can be useful to pinpoint PPR issues to trace them to their root cause for correction.

The present disclosure discloses an optical plasma species sensor (OPSS) that comprises a photo-sensor, a band-pass optical filter, and a collimator. The collimator restricts the incident angle so that only electromagnetic emission emitted from a certain solid angle above of the sensor is allowed through. Good spatial resolution is achieved because EM emissions from other parts of the process chamber are suppressed. The band-pass filter allows only electromagnetic emission at or near a specific wavelength to pass through. To make the sensor sensitive to only a specific chemical species, the band pass filter wavelength is selected at or near the emission peak of the specific chemical species. After the collimator and the band-pass filter the electromagnetic emission, the photo-sensor converts the electromagnetic emission signal at or near the specific wavelength to electrical data. The electrical data is a function of time. Alternatively, the filter may be a broadband filter that allows a wide spectral region of the plasma EM emissions to be detected by the photo-sensor.

The present disclosure also discloses an Optical Plasma Monitoring Apparatus (OPMA) that incorporates multiple OPSS to measure EM emissions of chemical species and/or broadband EM emissions in a PPR. The apparatus comprises a rigid carrier piece (RCP) in the form of a workpiece such as a semiconductor wafer, multiple OPSS, and ancillary electronics. The ancillary electronics are composed of an electrical connection piece (ECP) such as a Printed Circuit Board (PCB), analog-to-digital converter and information (ADCI) processor, electrical power source (EPS), a digital communication device (DCD), and an optional electrical charging device (ECD). The apparatus also has EM shielding to isolate the electronics and sensors from non-optical electromagnetic interference from the plasma and its excitation source. The apparatus may also have a barrier coating (BC) to isolate the components from the PPR to eliminate or minimize contamination from the OPMA to the PPR. The sensors, ancillary electronics, EM shielding, and BC are attached to the rigid piece in ways so that the assembled apparatus can be transferred into a plasma processing chamber like a workpiece such as a semiconductor wafer. Sensors are disposed at various locations on the carrier piece such that the strength and uniformity of EM emissions from the plasma above the carrier piece can be measured.

The present disclosure also discloses a system that comprises an OPMA, a charger, a receiver (optional), and a computing device. The OPMA comprises a transmitter to transmit data (e.g., to the receiver) out of the OPMA via a wireless channel. The computing device is configured to receive data from the receiver over a network or directly from the OPMA over the wireless channel, and analyze received data. The charger can charge the Power Source (PS) on the OPMA through a wireless or wired connection to the Electrical Charging Device (ECD) on the same apparatus.

The present disclosure further discloses a method of measuring and mapping plasma EM emissions in a PPR composed of the steps of transporting the OPMA apparatus into reactor, running a processing recipe with at least one plasma step, recording spatially and temporally the intensity of plasma lines and/or broadband plasma emissions with the OPMA, transporting the apparatus out of reactor, and downloading plasma emission data.

### BRIEF DESCRIPTION OF THE DRAWINGS

FIG. 1 illustrates an exemplary Optical Plasma Monitoring Apparatus (OPMA) within a Plasma Processing Reactor (PPR) collecting EM emission data from a plasma therein, in accordance with an implementation of the present disclosure;

FIG. 2 illustrates an exemplary optical plasma species sensor (OPSS) part of the OPMA in FIG. 1 interacting with the plasma therein, in accordance with an implementation of the present disclosure;

FIG. 3 illustrates an exemplary OPMA, in accordance with an implementation of the present disclosure;

FIG. 4 illustrates an exemplary process method for measuring and mapping plasma EM emissions in a PPR system, in accordance with an implementation of the present disclosure;

FIG. 5 illustrates an exemplary OPMA system, in accordance with an implementation of the present disclosure; and

FIGS. 6 and 7 illustrate exemplary systems, in accordance with an implementation of the present disclosure.

### DETAILED DESCRIPTION

The present disclosure can be embodied in many different forms. Representative embodiments are shown in the drawings, and will herein be described in detail. These embodiments are examples or illustrations of the principles of the disclosure but are not intended to limit its broad aspects. To that extent, elements and limitations that are disclosed, for example, in the Abstract, Summary, and Detailed Description sections, but not explicitly set forth in the claims, should not be incorporated into the claims, singly or collectively, by implication, inference, or otherwise. For purposes of the present detailed description, unless specifically disclaimed, the singular includes the plural and vice versa; and the word “including” means “including without limitation.” Moreover, words of approximation, such as “about,” “almost,” “substantially,” “approximately,” and the like, can be used herein to mean “at,” “near,” or “nearly at,” or “within 3-5% of,” or “within acceptable manufacturing tolerances,” or any logical combination thereof, for example.

Various examples of the present disclosure provide an OPMA that incorporates multiple OPSS to measure EM emissions of chemical species and/or broadband EM emissions in a PPR. The apparatus comprises a RCP in the form of a workpiece. The ancillary electronics are composed of an ECP, ADCI processor, EPS, a DCD, and an optional ECD. The apparatus also has EM shielding to isolate the electronics and sensors from non-optical electromagnetic interference from the plasma and its excitation source. The apparatus may also have a BC to isolate the components from the PPR to eliminate or minimize contamination from the OPMA to the PPR. The sensors, ancillary electronics, EM shielding, and BC are attached to the rigid piece in ways so that the assembled apparatus can be transferred into a plasma processing chamber like a workpiece. Sensors are disposed at various locations on the carrier piece such that the strength and uniformity of plasma EM emissions above the carrier piece can be measured.

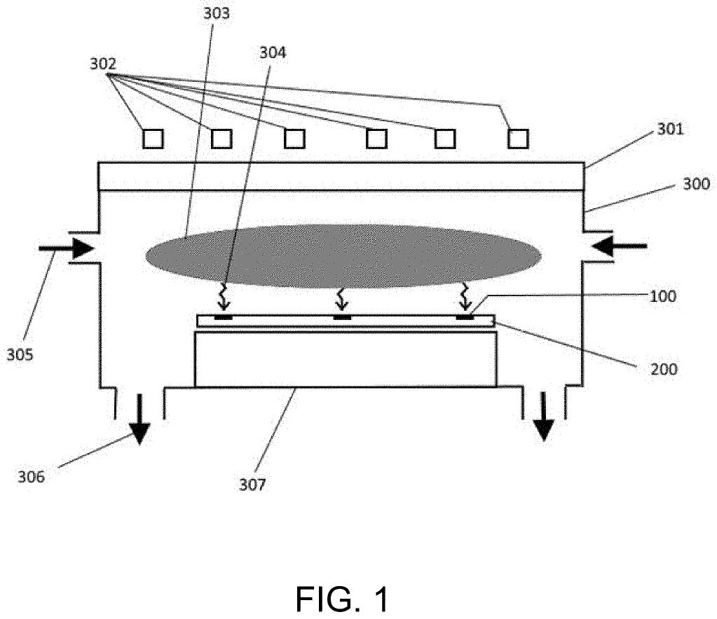

FIG. 1 illustrates an exemplary OPMA (200) within a PPR (300) collecting EM emission data from a plasma therein, in accordance with an implementation of the present disclosure. The PPR chamber (300) is generally operated with internal gas pressures well below atmospheric pressure. Processing gases, dictated by a processing recipe, enter (305) the PPR 300. In this PPR illustration, the top of the PPR comprises a dielectric window (301). A plasma excitation coil or electrode (302) energies the plasma (303). Byproduct gases and unused processing gases are pumped away (306). EM emissions (304) from the plasma are incident on the OPSS (100) that generates an electrical signal. Information from the electrical signal is then recorded by the OPMA (200).

In some implementations, the OPMA (200) can be constructed with physical characteristics similar to an actual workpiece such that it is transported into and out of the PPR (300) in the same manner as a workpiece. In this way, the OPMA (200) does not significantly alter the plasma characteristics, and can fit onto a PPR workpiece platen or an electrostatic chuck (307) and be electrostatically clamped in the same manner as an actual workpiece.

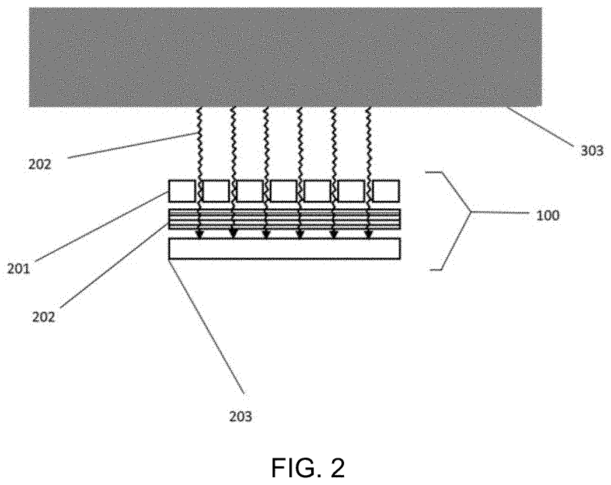

FIG. 2 illustrates an exemplary OPSS (100) of the OPMA (200) in FIG. 1 interacting with the plasma (303) therein, in accordance with an implementation of the present disclosure. The OPSS (100) comprises a collimator (201), bandpass filter (202) that may be constructed of many layers of dielectric materials, and photo-sensor (203). The collimator (201) can ensure that EM emissions from regions of the plasma (303) not directly above the OPSS (100) are not measured.

In some implementations, performance of the bandpass filter (202) are strongly angle dependent. The collimator (201) can ensure that EM emissions incident on the bandpass filter and photo-sensor strike at near a normal angle.

In this example, there may be adhesive between the components of the OPSS (100) in order to hold them together mechanically. The collimator (201) can be made of materials with low or no electromagnetic emission transparency.

In some implementations, hole(s) of the collimator (201) may be filled with a transparent material to prevent chemical species from the processing chamber to reaching and damaging the band-pass filter (202). In some implementations, a electromagnetic emission sensing device is integrated with either the band-pass filter (202) or the collimator (201) in one manufacturing process to reduce sensor thickness and cost. In some implementations, collimator (201), bandpass filter (202), and photo-sensor (203) of the OPSS (100) can be integrated in one manufacturing process, e.g., 3D microelectromechanical-system (MEMS) processes can be used to make integrated structures described in the current sensor.

The aspect ratio (defined as the ratio between the depth and the opening diameter) of the collimator is decided by the targeted spatial resolution of sensor and the sensitivity of the photo-sensor. Higher aspect ratio collimator can collect incident electromagnetic emission from smaller solid angle and therefore has higher spatial resolution, but the through electromagnetic emission intensity will reduce proportionally. In this example, a thin collimator (201) is used to control overall sensor thickness.

The wavelength and bandwidth of the bandpass filter (202) may depend on the spectral structure of intended chemical species. A wider emission peak requires a wider bandwidth. The chosen chemical species can be either reactant or reaction by-product. In this example, a reactant specie can be Fluorine (F) radical which has an emission peak at 703 nm. A reaction by product species can be SiF which has an emission peak at 777 nm. In some examples, species and wavelengths monitored by process chamber OES (Optical Emission Spectroscopy) are good candidates to use in the sensors (203) described in present disclosure.

In some implementations, a filter that allows a broad region of the spectrum (e.g. 500-750 nm) to pass can also be used to detect and map overall spectral intensity.

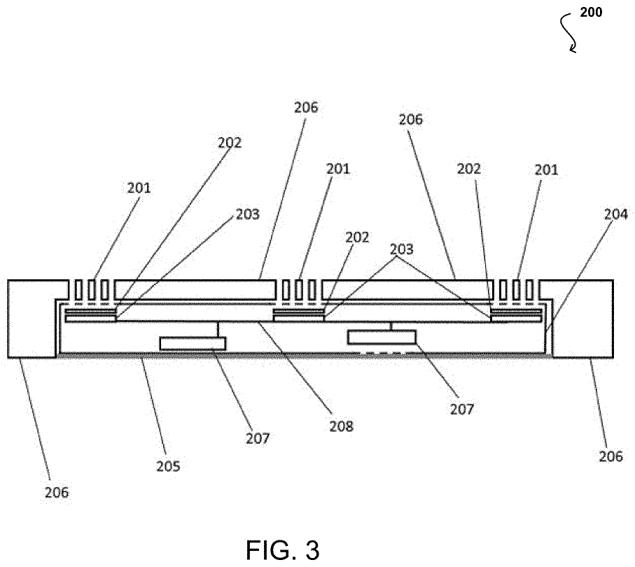

FIG. 3 illustrates an exemplary OPMA (200), in accordance with an implementation of the present disclosure. In this example, a rigid carrier (206), which may be made of the same materials as actual workpieces such as silicon or glass, has been constructed with a cavity to contain components. The collimator (201) of the OPSS may be integrated into the rigid carrier (206) or remain a separate piece that is inserted into a hole in the rigid carrier. Other OPSS components (the bandpass filter (202) and photo-sensor (203)), ancillary electronics (207), and electrical interconnect (208) are embedded in the cavity of the rigid carrier (206).

In some implementations, multiple filters and detectors can be grouped together (e.g. 703 nm for Fluorine (F), and 400-750 nm for overall plasma intensity) to allow sampling of different EM emissions at each selected location on the OPMA (200). Electrically active components of the OPMA (200) can be surrounded by EM shielding to prevent electromagnetic fields from interfering with electronics (207) and photo-sensor (203). The EM shielding may have patterns of holes to allow the EM emissions to pass through to the photo-sensor (203), and other optical or infrared communication signals to pass through to the ancillary electronics (207).

In some implementations, a barrier coating (BC) (205) can be applied to seal the cavity area to prevent trace contaminants (e.g. transitional metal elements) from the interior of the OPMA (200) from being transferred into the PPR upon use of the OPMA (200).

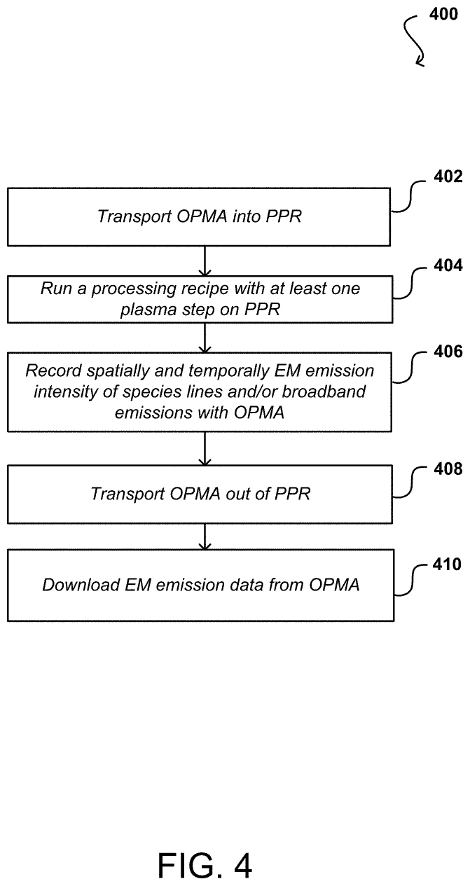

FIG. 4 illustrates an exemplary process method 400 for measuring and mapping plasma EM emissions in a PPR system, in accordance with an implementation of the present disclosure. It should be understood that the exemplary method 400 is presented solely for illustrative purposes, and that in other methods in accordance with the present disclosure can include additional, fewer, or alternative steps performed in similar or alternative orders, or in parallel. The exemplary method 400 starts at step 402 by transporting an OPMA into a PPR.

At step 404, the PPR system runs a recipe on the PPR that includes at least one plasma step. In some implementations, the recipe is the same or substantially the same as a targeted production recipe for actual semiconductor wafers on the PPR system.

At step 406, an OPSS of the OPMA can record the spatial and temporal dependent data of EM emissions from a plasma within the PPR while running the at least one plasma step, which is illustrated in FIGS. 1-3. In some implementations, the OPSS can also measure broadband emissions from the plasma.

The PPR system can transport the OPMA out of the PPR, at step 408, and then download recorded data from the OPMA to an off board computer system, at step 410.

In some implementations, the OPMA further comprises a transmitter (e.g., an IR transmitter) such that the OPMA can transmit the spatial and temporal dependent data of EM emissions to a receiver outside the PPR. The receiver can be coupled to a computing device associated with the PPR. Based on the spatial and temporal dependent data of EM emissions, the computing device can analyze the EM emissions, and may adjust the processing recipe in substantial real-time based at least upon the EM emissions.

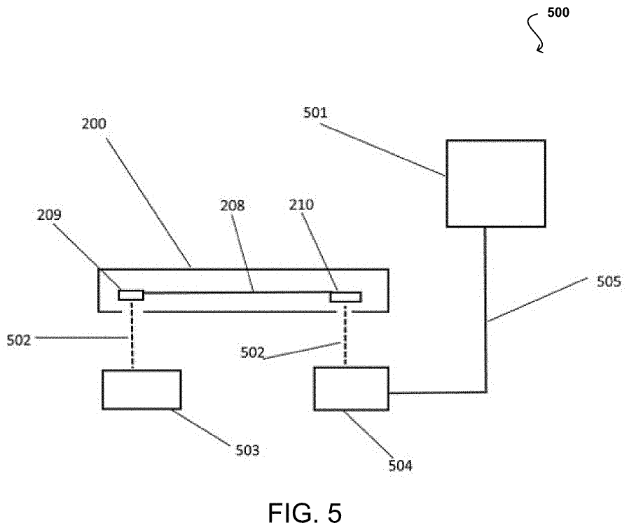

FIG. 5 illustrates an exemplary OPMA system (500), in accordance with an implementation of the present disclosure. In this example, the OPMA system (500) comprises an OPMA (200), a charger (503), a receiver (504), and a computing device (501). The computing device (501) is configured to receive data from the receiver (504) and analyze received data. The data relates to spatial and temporal dependent information of EM emissions from a plasma within a PPR while running at least one plasma step of a recipe.

The receiver (504) can receive data from a transmitter (210) of the OPMA (200) via a wireless channel (502) or a wired connection. The wireless channel (502) can be a suitable channel that enables the OPMA (200) to communicate wirelessly, such as Bluetooth, cellular, NFC, or Wi-Fi channels. The receiver (504) can then transmit received data to the computing device (501) via the network (505), or directly to a computing device associated the PPR.

In some implementations, the charger (503) can charge the power source on the OPMA (200) through a wireless or wired connection to an electrical charging device (ECD) (209) that is a part of the ancillary electronics on the OPMA (200). In one example, the charger (503) is a electromagnetic emission device, and the electrical charging device (209) is a photovoltaic device. In another example, the charger (503) is a Near field Charging (NFC) transmitter, and the ECD is a NFC receiver.

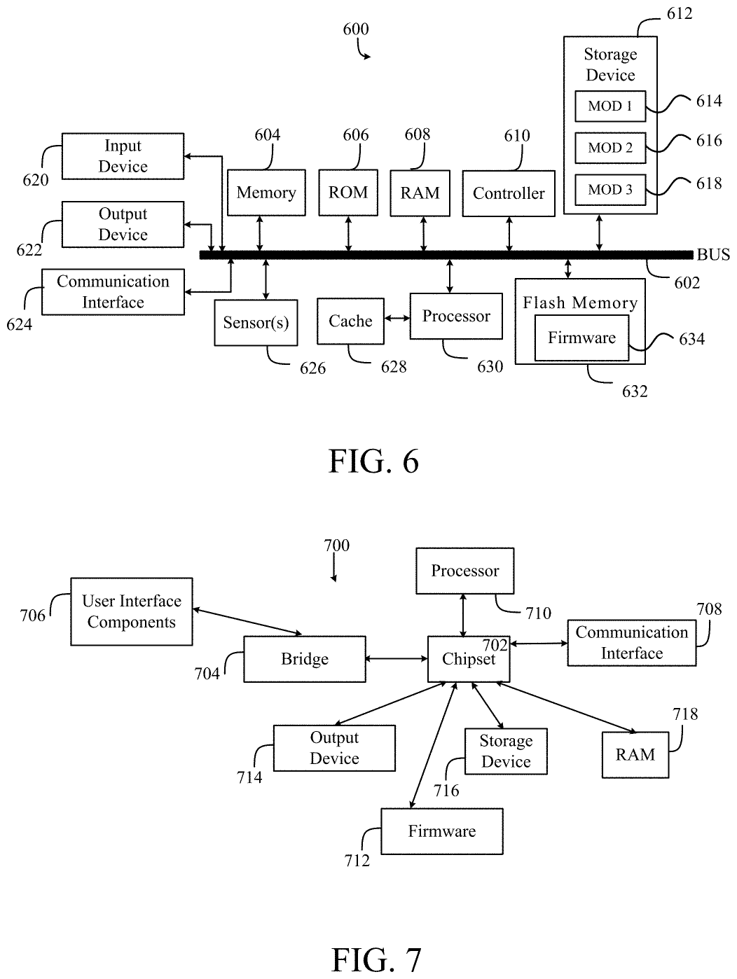

A brief introductory description of example systems and networks, as illustrated in FIGS. 6-7, is disclosed herein. These variations shall be described herein as the various examples are set forth. The present disclosure now turns to FIG. 6.

FIG. 6 illustrates an example computing system 600, in which components of the computing system are in electrical communication with each other using a bus 602. The system 600 includes a processing unit (CPU or processor) 630, and a system bus 602 that couples various system components, including the system memory 604 (e.g., read only memory (ROM) 606 and random access memory (RAM) 608), to the processor 630. The system 600 can include a cache of high-speed memory connected directly with, in close proximity to, or integrated as part of the processor 630. The system 600 can copy data from the memory 604 and/or the storage device 612 to the cache 628 for quick access by the processor 630. In this way, the cache can provide a performance boost for processor 630 while waiting for data. These and other modules can control or be configured to control the processor 630 to perform various actions. Other system memory 604 may be available for use as well. The memory 604 can include multiple different types of memory with different performance characteristics. The processor 630 can include any general purpose processor and a hardware module or software module, such as module 1 614, module 2 616, and module 3 618 embedded in storage device 612. The hardware module or software module is configured to control the processor 630, as well as a special-purpose processor where software instructions are incorporated into the actual processor design. The processor 630 may essentially be a completely self-contained computing system, and containing multiple cores or processors, a bus, memory controller, cache, etc. A multi-core processor may be symmetric or asymmetric.

To enable user interaction with the computing device 600, an input device 620 is provided as an input mechanism. The input device 620 can comprise a microphone for speech, a touch-sensitive screen for gesture or graphical input, keyboard, mouse, motion input, and so forth. In some instances, multimodal systems can enable a user to provide multiple types of input to communicate with the system 600. In this example, an output device 622 (e.g., a display) is also provided. The communications interface 624 can govern and manage the user input and system output.

Storage device 612 can be a non-volatile memory to store data that are accessible by a computer. The storage device 612 can be magnetic cassettes, flash memory cards, solid state memory devices, digital versatile disks, cartridges, random access memories (RAMs) 608, read only memory (ROM) 606, and hybrids thereof.

The controller 610 can be a specialized microcontroller or processor on the system 600, such as a BMC (baseboard management controller). In some cases, the controller 610 can be part of an Intelligent Platform Management Interface (IPMI). Moreover, in some cases, the controller 610 can be embedded on a motherboard or main circuit board of the system 600. The controller 610 can manage the interface between system management software and platform hardware. The controller 610 can also communicate with various system devices and components (internal and/or external), such as controllers or peripheral components, as further described below.

The controller 610 can generate specific responses to notifications, alerts, and/or events, and communicate with remote devices or components (e.g., electronic mail message, network message, etc.) to generate an instruction or command for automatic hardware recovery procedures, etc. An administrator can also remotely communicate with the controller 610 to initiate or conduct specific hardware recovery procedures or operations, as further described below.

The controller 610 can also include a system event log controller and/or storage for managing and maintaining events, alerts, and notifications received by the controller 610. For example, the controller 610 or a system event log controller can receive alerts or notifications from one or more devices and components, and maintain the alerts or notifications in a system event log storage component.

Flash memory 632 can be an electronic non-volatile computer storage medium or chip that can be used by the system 600 for storage and/or data transfer. The flash memory 632 can be electrically erased and/or reprogrammed. Flash memory 632 can include EPROM (erasable programmable read-only memory), EEPROM (electrically erasable programmable read-only memory), ROM, NVRAM, or CMOS (complementary metal-oxide semiconductor), for example. The flash memory 632 can store the firmware 634 executed by the system 600, when the system 600 is first powered on, along with a set of configurations specified for the firmware 634. The flash memory 632 can also store configurations used by the firmware 634.

The firmware 634 can include a Basic Input/Output System or equivalents, such as an EFI (Extensible Firmware Interface) or UEFI (Unified Extensible Firmware Interface). The firmware 634 can be loaded and executed as a sequence program each time the system 600 is started. The firmware 634 can recognize, initialize, and test hardware present in the system 600 based on the set of configurations. The firmware 634 can perform a self-test, such as a POST (Power-on-Self-Test), on the system 600. This self-test can test functionality of various hardware components such as hard disk drives, optical reading devices, cooling devices, memory modules, expansion cards, and the like. The firmware 634 can address and allocate an area in the memory 604, ROM 606, RAM 608, and/or storage device 612, to store an operating system (OS). The firmware 634 can load a boot loader and/or OS, and give control of the system 600 to the OS.

The firmware 634 of the system 600 can include a firmware configuration that defines how the firmware 634 controls various hardware components in the system 600. The firmware configuration can determine the order in which the various hardware components in the system 300 are started. The firmware 634 can provide an interface, such as an UEFI, that allows a variety of different parameters to be set, which can be different from parameters in a firmware default configuration. For example, a user (e.g., an administrator) can use the firmware 634 to specify clock and bus speeds; define what peripherals are attached to the system 600; set monitoring of health (e.g., fan speeds and CPU temperature limits); and/or provide a variety of other parameters that affect overall performance and power usage of the system 600. While firmware 634 is illustrated as being stored in the flash memory 632, one of ordinary skill in the art will readily recognize that the firmware 634 can be stored in other memory components, such as memory 604 or ROM 606.

System 600 can include one or more sensors 626. The one or more sensors 626 can include, for example, one or more temperature sensors, thermal sensors, oxygen sensors, chemical sensors, noise sensors, heat sensors, current sensors, voltage detectors, air flow sensors, flow sensors, infrared thermometers, heat flux sensors, thermometers, pyrometers, etc. The one or more sensors 626 can communicate with the processor, cache 628, flash memory 632, communications interface 624, memory 604, ROM 606, RAM 608, controller 610, and storage device 612, via the bus 602, for example. The one or more sensors 626 can also communicate with other components in the system via one or more different means, such as inter-integrated circuit (I2C), general purpose output (GPO), and the like. Different types of sensors (e.g., sensors 626) on the system 600 can also report to the controller 610 on parameters, such as cooling fan speeds, power status, operating system (OS) status, hardware status, and so forth.

FIG. 7 illustrates an example computer system 700 having a chipset architecture that can be used in executing the described method(s) or operations, and in generating and displaying a graphical user interface (GUI). Computer system 700 can include computer hardware, software, and firmware that can be used to implement the disclosed technology. System 700 can include a processor 710, representative of a variety of physically and/or logically distinct resources capable of executing software, firmware, and hardware configured to perform identified computations. Processor 710 can communicate with a chipset 702 that can control input to and output from processor 710. In this example, chipset 702 outputs information to output device 714, such as a display, and can read and write information to storage device 716, which can include magnetic media, and solid state media, for example. Chipset 702 can also read data from and write data to RAM 718. A bridge 704 for interfacing with a variety of user interface components 706, can be provided for interfacing with chipset 702. Such user interface components 706 can include a keyboard, a microphone, touch detection and processing circuitry, a pointing device, such as a mouse, and so on. In general, inputs to system 700 can come from any of a variety of sources, machine generated and/or human generated.

Chipset 702 can also interface with one or more communication interfaces 408 that can have different physical interfaces. Such communication interfaces can include interfaces for wired and wireless local area networks, for broadband wireless networks, and for personal area networks. Further, the machine can receive inputs from a user via user interface components 706 and execute appropriate functions, such as browsing functions by interpreting these inputs using processor 710.

Moreover, chipset 702 can also communicate with firmware 712, which can be executed by the computer system 700 when powering on. The firmware 712 can recognize, initialize, and test hardware present in the computer system 700 based on a set of firmware configurations. The firmware 712 can perform a self-test, such as a POST, on the system 700. The self-test can test the functionality of the various hardware components 702-718. The firmware 712 can address and allocate an area in the memory 718 to store an OS. The firmware 712 can load a boot loader and/or OS, and give control of the system 700 to the OS. In some cases, the firmware 712 can communicate with the hardware components 702-710 and 714-418. Here, the firmware 712 can communicate with the hardware components 702-710 and 714-718 through the chipset 702, and/or through one or more other components. In some cases, the firmware 712 can communicate directly with the hardware components 702-710 and 714-718.

It can be appreciated that example systems 600 and 700 can have more than one processor (e.g., 630, 710), or be part of a group or cluster of computing devices networked together to provide greater processing capability.

For clarity of explanation, in some instances, the present disclosure may be presented as including individual functional blocks including functional blocks, including devices, device components, steps or routines in a method embodied in software, or combinations of hardware and software.

In some embodiments, the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Methods according to the above-described examples can be implemented using computer-executable instructions that are stored or otherwise available from computer readable media. Such instructions can include, for example, instructions and data which cause or otherwise configure a general purpose computer, special purpose computer, or special purpose processing device to perform a certain function or group of functions. Portions of computer resources used, can be accessible over a network. The computer executable instructions may be, for example, binaries and intermediate format instructions, such as assembly language, firmware, or source code.

Devices implementing methods according to these disclosures can include hardware, firmware and/or software, and can take any of a variety of form factors. Typical examples of such form factors include laptops, smart phones, small form factor personal computers, personal digital assistants, rack-mount devices, standalone devices, and so on. Functionality described herein also can be embodied in peripherals or add-in cards. Such functionality can also be implemented on a circuit board among different chips, or different processes executing in a single device, by way of further example.

The various examples can be further implemented in a wide variety of operating environments, which in some cases can include one or more server computers, user computers or computing devices which can be used to operate any of a number of applications. User or client devices can include any of a number of general purpose personal computers, such as desktop or laptop computers running a standard operating system, as well as cellular, wireless, and handheld devices running mobile software, and capable of supporting a number of networking and messaging protocols. Such a system can also include a number of workstations running any of a variety of commercially-available operating systems, and other known applications for purposes such as development and database management. These devices can also include other electronic devices, such as dummy terminals, thin-clients, gaming systems, and other devices capable of communicating via a network.

To the extent examples, or portions thereof, are implemented in hardware, the present disclosure can be implemented with any, or a combination of, the following technologies: a discreet logic circuit(s) having logic gates for implementing logic functions upon data signals; an application specific integrated circuit (ASIC) having appropriate combinational logic gates; programmable hardware such as a programmable gate array(s) (PGA); and/or a field programmable gate array (FPGA); etc.

Most examples utilize at least one network that would be familiar to those skilled in the art for supporting communications using any of a variety of commercially-available protocols, such as TCP/IP, OSI, FTP, UPnP, NFS, CIFS, AppleTalk etc. The network can be, for example, a local area network, a wide-area network, a virtual private network, the Internet, an intranet, an extranet, a public switched telephone network, an infrared network, a wireless network, and any combination thereof.

Devices implementing methods, according to these technologies, can include hardware, firmware and/or software, and can take any of a variety of form factors. Typical examples of such form factors include server computers, laptops, smart phones, small form factor personal computers, personal digital assistants, and so on. Functionality described herein also can be embodied in peripherals or add-in cards. Such functionality can also be implemented on a circuit board among different chips, or different processes executing in a single device, by way of further example.

In examples that utilize a Web server, the Web server can run any variety of server or mid-tier applications, including HTTP servers, FTP servers, CGI servers, data servers, Java servers, and business application servers. In response to requests from user devices, the Web server(s) can also be capable of executing programs or scripts. For example, the Web server can execute one or more Web applications, which can be implemented as one or more scripts or programs written in any programming language, such as Java®, C, C# or C++ or any scripting language, such as Perl, Python or TCL, as well as combinations thereof. The Web server(s) can also encompass database servers, including those commercially available on the open market.

The server system can include a variety of data stores and other memory and storage media, as discussed above. These can reside in a variety of locations, such as on a storage medium local to (and/or resident in) one or more of the computers, or remote from any or all of the computers across the network. In a particular set of examples, the information can reside in a storage-area network (SAN) familiar to those skilled in the art. Similarly, any necessary files for performing the functions attributed to the computers, servers, or other network devices can be stored locally and/or remotely, as appropriate. Where a system includes computerized devices, each such device can include hardware elements that can be electrically coupled via a bus, the elements including, for example, at least one central processing unit (CPU), at least one input device (e.g., a mouse, keyboard, controller, touch-sensitive display element or keypad), and at least one output device (e.g., a display device, printer or speaker). Such a system can also include one or more storage devices, such as disk drives, optical storage devices, and solid-state storage devices such as random access memory (RAM) or read-only memory (ROM), as well as removable media devices, memory cards, flash cards, etc.

Storage media and computer readable media for containing code, or portions of code, can include any appropriate media known or used in the art, including, but are not limited to, removable and non-removable media for storage and/or transmission of data or information. The removable and non-removable media comprise RAM, ROM, EPROM, EEPROM, flash memory or other memory technology, CD-ROM, digital versatile disk (DVD) or other optical storage, magnetic cassettes, magnetic tape, magnetic disk storage, or other magnetic storage devices that can be used to store the desired information and that can be accessed by a system device. The data or information can include computer readable instructions, data structures, program modules, or other data. Based on the technology and teachings provided herein, a person of ordinary skill in the art will appreciate other ways and/or methods to implement the various aspects of the present disclosure.

The specification and drawings are, accordingly, to be regarded in an illustrative rather than a restrictive sense. It will, however, be evident that various modifications and changes can be made thereunto without departing from the broader spirit and scope of the patent application, as set forth in the claims.

1. An apparatus for measuring plasma emissions in a plasma processing reactor (PPR), comprising:
a collimator configured to restrict incident angles such that only electromagnetic emissions with a specific range of angles pass through, the electromagnetic emissions emitted from a plasma inside the PPR;
a band-pass filter configured to allow the electromagnetic emissions at or near a specific wavelength to pass through; and
a plurality of photo-sensors configured to convert the electromagnetic emissions at or near the specific wavelength to electrical data, the electrical data being recorded on a non-transitory computer-readable storage medium of the apparatus.

2. The apparatus of claim 1, wherein the specific wavelength is at or near an emission peak of a specific chemical specie.

3. The apparatus of claim 1, wherein the band-pass filter is a broadband filter that allows a wide spectral region of the electromagnetic emissions to be detected by the plurality of photo-sensors.

4. The apparatus of claim 1, further comprising:
a rigid carrier piece (RCP) in a form of a workpiece; and
ancillary electronics.

5. The apparatus of claim 4, wherein the ancillary electronics comprise an electrical connection piece (ECP), an analog-to-digital converter and information (ADCI) processor, an electrical power source (EPS), a digital communication device (DCD), and an optional electrical charging device (ECD).

6. The apparatus of claim 5, wherein the ECD is a photovoltaic device.

7. The apparatus of claim 5, further comprising an Electromagnetic (EM) shielding to isolate the ancillary electronics and the plurality of photo-sensors from non-optical electromagnetic interference from the plasma and the plasma's excitation source inside the PPR.

8. The apparatus of claim 7, further comprising a barrier coating (BC) to isolate components of the apparatus from the PPR to protect the PPR from contamination from the apparatus.

9. The apparatus of claim 8, wherein the plurality of photo-sensors is disposed at various locations of the RCP such that strength and uniformity information of EM emissions from the plasma above the RCP is measured.

10. The apparatus of claim 9, wherein the apparatus is coupled to a charger, a receiver, and a computing device associated with the PPR, the charger configured to charge a Power Source (PS) on the apparatus through a wireless or wired connection to the ECD.

11. The apparatus of claim 10, wherein the apparatus further comprises a transmitter configured to transmit the electrical data to the receiver via a wireless channel, the receiver being located outside the PPR.

12. The apparatus of claim 11, wherein the computing device is configured to receive the electrical data from the receiver over the wireless channel, or directly from the apparatus over the wireless channel; and further analyze received the electrical data.

13. The apparatus of claim 12, wherein the computing device is further configured to analyze received electrical data, and adjust a processing recipe running on the PPR in substantial real-time.

14. A computer-implemented method measuring plasma emissions in a plasma processing reactor (PPR), comprising:
transporting an Optical Plasma Monitoring Apparatus (OPMA) into the PPR, wherein the OPMA comprises a collimator, a band-pass filter, and a plurality of photo-sensors;
running a recipe on the PPR that includes at least one plasma step;
recording spatial and temporal dependent data of EM emissions from a plasma within the PPR while running the at least one plasma step; and
transporting the OPMA out of the PPR.

15. The computer-implemented method of claim 14, further comprising:
analyzing received electrical data; and
adjusting the recipe running on the PPR in substantial real-time.

16. The computer-implemented method of claim 14, wherein the OPMA further comprises a rigid carrier piece (RCP) in a form of a workpiece; and ancillary electronics.

17. The computer-implemented method of claim 16, wherein the ancillary electronics comprise an electrical connection piece (ECP), an analog-to-digital converter and information (ADCI) processor, an electrical power source (EPS), a digital communication device (DCD), and an optional electrical charging device (ECD).

18. The computer-implemented method of claim 17, wherein the OPMA further comprises an Electromagnetic (EM) shielding to isolate the ancillary electronics and the plurality of photo-sensors from non-optical electromagnetic interference from the plasma and the plasma's excitation source inside the PPR.

19. The computer-implemented method of claim 18, wherein the OPMA further comprises a barrier coating (BC) to isolate components of the OPMA from the PPR to protect the PPR from contamination from the OPMA.

20. The computer-implemented method of claim 19, wherein the OPMA is coupled to a charger, a receiver, and a computing device associated with the PPR, the charger configured to charge a Power Source (PS) on the OPMA through a wireless or wired connection to the ECD.
